(19) United States
(12) Patent Application Publication
(10) Pub. No.: US 2006/0121684 A1
(43) Pub. Date: Jun. 8, 2006

(54) METHOD OF FORMING A POLYSILICON RESISTOR

(76) Inventor: Cheng-Hsiung Chen, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/307,503

(22) Filed: Feb. 10, 2006

Related U.S. Application Data
(63) Continuation of application No. 10/711,376, filed on Sep. 15, 2004.

(51) Int. Cl. H01L 21/20

(52) U.S. Cl. 438/385

(57) ABSTRACT

A method of forming a polysilicon resistor includes: providing a substrate, the substrate comprising a dielectric layer; forming a polysilicon layer on the dielectric layer; doping the entire polysilicon layer evenly with first type dopants; doping said polysilicon layer containing the first type dopants with second type dopants; defining a polysilicon resistor pattern on the polysilicon layer and removing the polysilicon layer and the dielectric layer outside the polysilicon resistor pattern down to the surface of the substrate, the remainder of the polysilicon layer comprising at least a high resistance region and a low resistance region; and forming a salicide layer on the remainder of the polysilicon layer within the low resistance region.

### CROSS REFERENCE TO RELATED APPLICATIONS

This is a continuation application of U.S. application Ser. No. 10/711,376, filed Sep. 15, 2004, which is hereby incorporated by reference in its entirety.

### BACKGROUND OF THE INVENTION

1. Field of the Invention

The present invention relates to a method of forming a polysilicon resistor, and more particularly, to a method of forming a polysilicon resistor capable of providing a stable value of high resistance.

2. Description of the Prior Art

In a semiconductor process, polysilicon is often positioned to function as resistors capable of providing high resistance. These resistors can be used in place of load transistors. When load transistors of a static random access memory (SRAM) is replaced by polysilicon resistors, the number of transistors in the SRAM can be reduced and thus saves cost and enhance the integration of the SRAM.

Referring to FIGS. 1-3, FIGS. 1-3 are schematic diagrams of a method of forming a polysilicon resistor according to the prior art. As shown in FIG. 1, a substrate 10 is provided. A dielectric layer 12 and a polysilicon layer 14 are formed on the substrate 10, respectively. Then, as shown in FIG. 2, a photolithographic process and an etching process are performed to remove portions of the polysilicon layer 14 and the dielectric layer 12 down to the surface of the substrate 10, thus defining the pattern of the polysilicon resistor. Normally, the polysilicon resistor has a sandwich-like structure that sandwiches a high resistance polysilicon region between two low resistance polysilicon ends. The low resistance polysilicon ends are provided for forming interconnection contact plugs to connect the polysilicon resistor with other wirings. The high resistance polysilicon region is used to provide a high resistance to satisfy circuit designs or device demands.

As shown in FIG. 3, the resistance at different regions of the polysilicon resistor is now adjusted to define the high resistance region and the low resistance regions at both sides of the high resistance region. For example, a photolithographic process is performed to form a mask layer 16 on the polysilicon layer 14 to cover the region for forming the high resistance region. Following that, an ion implantation process is performed using N-type or P-type dopants to dope the portions of the polysilicon layer 14 not covered by the mask layer 16, thus reducing the resistance of the portions of the polysilicon layer 14 at the either side of the high resistance region. Since the portions of the polysilicon layer 14 in the undoped region has higher resistance than the portions of the polysilicon layer 14 in the doped region, the high resistance region and the low resistance regions are now defined to complete the fabrication of the polysilicon resistor. In order to satisfy the electrical characteristics demands of the products, sometimes a lightly doping process (such as an N-doping or P-doping) is used to dope the entire surface of the polysilicon layer 14, including the low resistance regions and the high resistance region. Following that, a heavily doping process (such as an N+ doping or P+ doping) is performed using the same type dopants to dope the portions of the polysilicon layer 14 at the low resistance regions.

With the development of the various electronic products, circuit designs applying poysilicon resistors to replace load resistors become more and more complicated. For example, for the analog/digital mixed mode integrated circuits or the radio frequency integrated circuits, it is required that the load resistors have a high value of ohmic resistance and the value of the ohmic resistance must further be within tight limits. Therefore, how to produce load resistors with a stable value of high resistance and decrease cross section areas of the load resistors for enhancing the device integration are very important for the application of the polysilicon resistors.

### SUMMARY OF THE INVENTION

It is therefore an object of the claimed invention to providing a method of forming a polysilicon resistor capable of providing a stable value of high resistance.

According to the claimed invention, a method of forming a polysilicon resistor includes: providing a substrate, the substrate comprising a dielectric layer; forming a polysilicon layer on the dielectric layer; doping the entire polysilicon layer evenly with first type dopants; doping said polysilicon layer containing the first type dopants with second type dopants; defining a polysilicon resistor pattern on the polysilicon layer and removing the polysilicon layer and the dielectric layer outside the polysilicon resistor pattern down to the surface of the substrate, the remainder of the polysilicon layer comprising at least a high resistance region and a low resistance region; and forming a salicide layer on the remainder of the polysilicon layer within the low resistance region.

It is an advantage of the present invention that the first type dopants and the second type dopants are used to adjust the resistance of the portions of the polysilicon layer within the high resistance region. Being controlled by the dosage adjustment of the first type dopants and the second type dopants, a uniform and stable value of high resistance is therefore obtained to satisfy the circuit designs. In this case, a cross section area of the polysilicon resistor can also be reduced to enhance the device integration.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 are schematic diagrams of a method of forming a polysilicon resistor according to the prior art.

FIGS. 4-9 are schematic diagrams of a method of forming a polysilicon resistor according to the present invention.

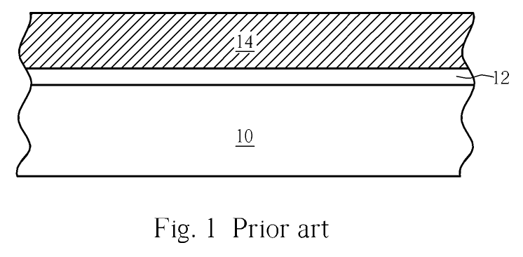

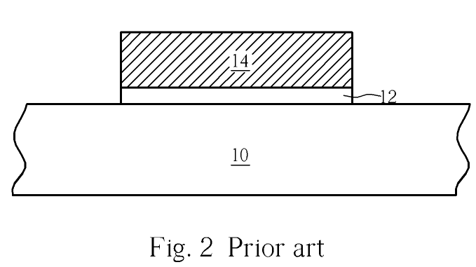

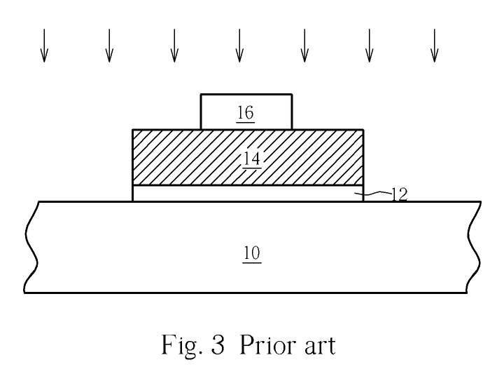

### DETAILED DESCRIPTION

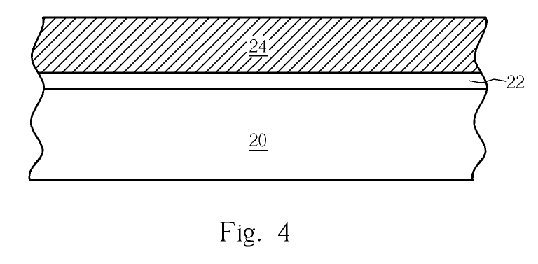

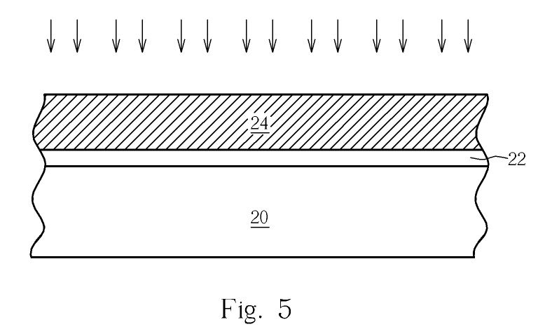

Referring to FIGS. 4-9, FIGS. 4-9 are schematic diagrams of a method of forming a polysilicon resistor according to the present invention. As shown in FIG. 4, a dielectric layer 22 and a polysilicon layer 24 are formed on a substrate 20, respectively. Following that, as shown in FIG. 5, an ion implantation process is performed using both of N-type dopants and P-type dopants to dope the polysilicon layer 24, thus adjusting the resistance of the polysilicon layer 24. In a better embodiment of the present invention, a dosage of the N-type dopants and a dosage of the P-type dopants have the same order of magnitude. For example, the N-type dopants can be As− ions with a dosage of approximate 3E15, and the P-type dopants can be BF₂+ ions with a dosage of approximate 1.5E15. However, the present invention is not limited, other N-type dopants (such as P or Sb) and P-type dopants (such as Ge or B) having the same order of magnitude can also be applied in the present invention to adjust the resistance of the polysilicon layer 24. When a cross section area of the polysilicon layer 24 of 100 μm×10 μm is suggested, a high resistance value of approximate 29 kohm/sq for the polysilicon layer 24 can be obtained. Since the variance for 25 wafers is measured to below 5%, an excellent uniformity in the polysilicon resistors can also be obtained according to the present invention.

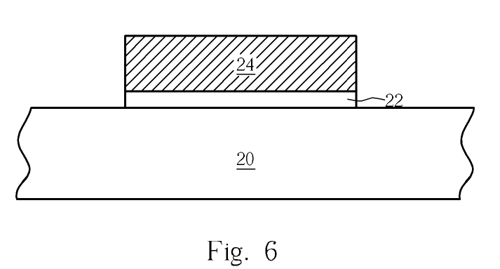

As shown in FIG. 6, a photolithographic process and an etching process are then used to remove portions of the polysilicon layer 24 and the dielectric layer 22 down to the surface of the substrate 20, thus defining the pattern of the polysilicon resistor. Alternatively, the pattern of the polysilicon resistor can be defined using the photolithographic process and the etching process prior to the ion implantation process using both of the N-type dopants and the P-type dopants for adjusting the resistance of the polysilicon layer 24.

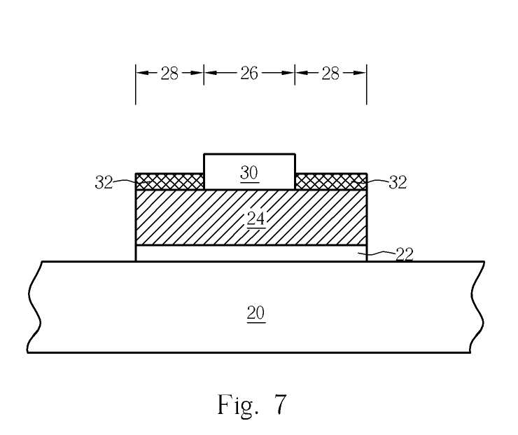

As shown in FIG. 7, a high resistance region 26 is defined at a central region of the polysilicon layer 24, and at least a low resistance region 28 is defined at the either side of the high resistance region 26. Following that, a salicide block (SAB) 30 is formed on the portions of the polysilicon layer 24 within the high resistance region 26. Using the SAB 30 as a mask, a salicide layer 32 is formed on the portions of the polysilicon layer 24 within the low resistance region 28. An example of the methods of forming the SAB 30 and the salicide layer 32 is further explained below. A dielectric layer (not shown) is deposited on the surface of the substrate 20 followed by using a photolithographic process and an etching process to completely remove the portions of the dielectric layer in the low resistance region 28, thus forming the SAB 30 by the remainder of the dielectric layer in the high resistance region 26. Subsequently, a salicide process is performed by first using a physical vapor deposition (PVD) method to sputter a metal layer (not shown) on the surface of the substrate 20. The metal layer is composed of tungsten or titanium. A thermal treatment process is thereafter performed to allow the reaction of the metal layer with the portions of the polysilicon layer 24 in the low resistance region 28, thus forming the salicide layer 32.

In a better embodiment of the present invention, the polysilicon resistor has a sandwich-like structure which sandwiches the high resistance region 26 for providing high resistance between two low resistance regions 28 for forming the interconnection contact plugs. The present invention is characterized by using two different types of dopants to adjust the polysilicon resistance in the high resistance region, and forming the salicide layer to reduce the polysilicon resistance in the low resistance region. Therefore, the present invention is not limited to the sandwich-like polysilicon resistor, and can also be applied in the polysilicon resistors of other structures to adjust the polysilicon resistance thereof.

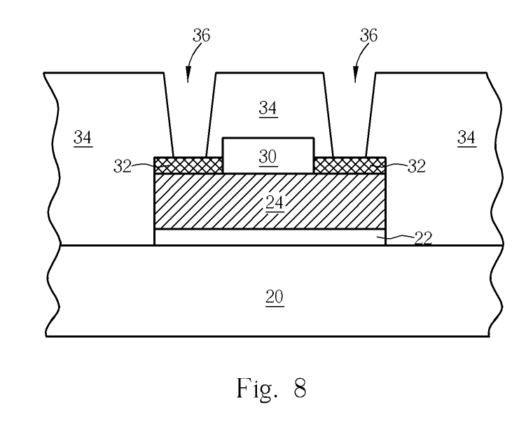

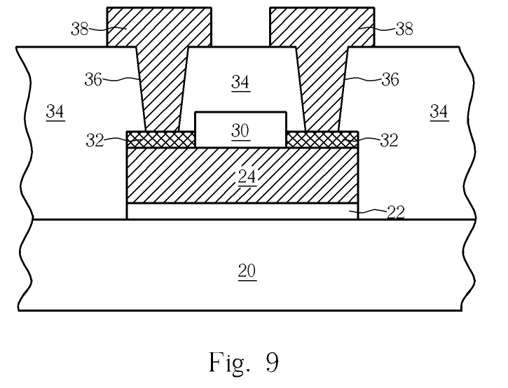

FIGS. 8 and 9 illustrate a method of forming an interconnection between the polysilicon resistor and other wirings. As shown in FIG. 8 and FIG. 9, an inter layer dielectric (ILD) 34, such as a silicon oxide layer or a borophosphosilicate glass (BPSG), is formed on the surface of the substrate 20 to insulate the salicide layer 32 from other conductive materials. Following that, a photolithographic process and an etching process are performed to form at least a contact hole 36 in the inter layer dielectric 34 to connect to the salicide layer 32. A conductive layer 38 is then formed on portions of the inter layer dielectric 34 and within the contact hole 36, thus connecting the polysilicon resistor to wirings formed above the inter layer dielectric 34 via the conductive layer 38 filling in the contact hole 36.

In contrast to the prior art method of forming the polysilicon resistor, the present invention uses two different types of dopants to adjust the polysilicon resistance in the high resistance region. Being controlled by the dosage of the dopants, the polysilicon resistance in the high resistance region has a value ranging between ten and thousands kohm/sq according to the present invetion. Therefore, the polysilicon resistor of the present invention is capable of providing a uniform and stable value of high resistance to satisfy the high resistance requirements for the SRAM, analog, digital/analog mixed mode and radio frequency circuit designs. In this case, a cross section area of the polysilicon resistor can also be reduced to enhance the device integration.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a polysilicon resistor, the method comprising:
providing a substrate, the substrate comprising a dielectric layer;
forming a polysilicon layer on the dielectric layer;
doping the entire polysilicon layer evenly with first type dopants;
doping said polysilicon layer containing the first type dopants with second type dopants;
defining a polysilicon resistor pattern on the polysilicon layer and removing the polysilicon layer and the dielectric layer outside the polysilicon resistor pattern down to the surface of the substrate, the remainder of the polysilicon layer comprising at least a high resistance region and a low resistance region; and
forming a salicide layer on the remainder of the polysilicon layer within the low resistance region.

2. The method of claim 1wherein the first type dopants comprise N-type dopants and the second type dopants comprise P-type dopants.

3. The method of claim 1wherein a dosage of the first type dopants and a dosage of the second type dopants have the same order of magnitude.

4. The method of claim 1further comprising forming a salicide block on the remainder of the polysilicon layer within the high resistance region.

5. The method of claim 1further comprising:
forming an inter layer dielectric on the substrate, the inter layer dielectric comprising at least a contact hole connecting to the salicide layer; and
forming a conductive layer on portions of the inter layer dielectric and within the contact hole.

6. The method of claim 1wherein the low resistance region is on the either side of the high resistance region.

7. A method of forming a polysilicon resistor, the method comprising:
providing a substrate, the substrate comprising a dielectric layer;
forming a polysilicon layer on the dielectric layer, wherein the polysilicon layer comprises a middle area having a high resistance and two side areas having a low resistance;
doping said middle area and said two side areas of the polysilicon layer with first type dopants;
doping said middle area and said two side areas of the polysilicon layer containing the first type dopants with second type dopants;
forming a salicide block on said middle area of the polysilicon layer; and
forming a salicide layer on said two side areas of the polysilicon layer.

8. The method of claim 7 wherein the first type dopants comprise N-type dopants and the second type dopants comprise P-type dopants.

9. The method of claim 7 wherein a dosage of the first type dopants and a dosage of the second type dopants have the same order of magnitude.

10. The method of claim 7 further comprising:
forming an inter layer dielectric on the substrate, the inter layer dielectric comprising at least a contact hole connecting to the salicide layer; and
forming a conductive layer on portions of the inter layer dielectric and within the contact hole.
